(19) United States
(12) Patent Application Publication
(10) Pub. No.: US 2026/0190988 A1
(43) Pub. Date: Jul. 2, 2026

(54) ELECTRONIC DEVICE

(71) Applicant: InnoLux Corporation, Miao-Li County (TW)

(72) Inventors: Yung-Chieh TSENG, Miao-Li County (TW); Po-Yun HSU, Miao-Li County (TW); Wen-Hsiang LIAO, Miao-Li County (TW)

(21) Appl. No.: 19/403,491

(22) Filed: Nov. 28, 2025

Related U.S. Application Data
(60) Provisional application No. 63/738,837, filed on Dec. 26, 2024.

(30) Foreign Application Priority Data
Aug. 26, 2025 (CN) 202511196014.X

(51) Int. Cl. H10W 40/22; H10W 70/685

(52) U.S. Cl. CPC H10W 40/22; H10W 70/685

(57) ABSTRACT

Electronic device is provided. The electronic device includes a substrate, an electronic element, a heat sink, a circuit board, a first conductive element, and a first heat dissipation element. The substrate has a first surface and a second surface opposite to each other. The electronic element is disposed on the first surface of the substrate. The heat sink is disposed on the electronic element. The circuit board is disposed on the second surface of the substrate. The first conductive element penetrates the substrate and electrically connects the electronic element and the circuit board. The first heat dissipation element penetrates the substrate and the circuit board, wherein the first heat dissipation element thermally exchanges with the heat sink.

### CROSS REFERENCE TO RELATED APPLICATIONS

This application claims the benefit of U.S. provisional application No. 63/738,837, filed December. 26, 2024, the entirety of which is incorporated by reference herein.

This Application also claims priority of China Patent Application No. 202511196014.X, filed on August 26, 2025, the entirety of which is incorporated by reference herein.

### TITLE

### BACKGROUND OF THE DISCLOSURE

### Field of the Disclosure

The present disclosure relates to an electronic device, and in particular, it relates to an electronic device including a heat sink.

### Description of the Related Art

Electronic devices including display panels, such as displays, smartphones, tablet computers, notebook computers, and televisions, have become indispensable necessities in modern society. With the vigorous development of such electronic devices, consumers have come to have high expectations regarding the quality, functionality, or price of these electronic devices.

In general, the operation of an electronic device generates a large amount of heat, and this heat needs to be promptly and effectively directed away from the device. Failure to dissipate the heat promptly and effectively may lead to a sudden temperature rise in the device, resulting in operational failure, or possibly damage to the device. Accordingly, these electronic devices do not meet consumer expectations in every respect, and there are still some problems with such electronic devices. The development of improved electronic devices remains one of the current objectives.

### BRIEF SUMMARY OF THE DISCLOSURE

In some embodiments, an electronic device is provided. The electronic device includes a substrate, an electronic element, a heat sink, a circuit board, a first conductive element, and a first heat dissipation element. The substrate has an upper surface and a lower surface. The electronic element is disposed on the upper surface of the substrate. The heat sink is disposed on the electronic element. The circuit board is disposed on the lower surface of the substrate. The first conductive element penetrates the substrate and electrically connects the electronic element and the circuit board. The first heat dissipation element penetrates the substrate and the circuit board, wherein the first heat dissipation element thermally exchanges with the heat sink.

The electronic device of the present disclosure may be applied to various types of electronic equipment. To make the features and advantages of the present disclosure more clearly understood, various embodiments are given below, accompanied with the attached drawings for detailed description as below.

### BRIEF DESCRIPTION OF THE DRAWINGS

The present disclosure can be more fully understood by reading the subsequent detailed description and examples with references made to the accompanying drawings, wherein:

FIGS. 1 shows a cross-sectional view of an electronic device according to some embodiments of the present disclosure;

FIGS. 2 to 7 show cross-sectional views of a heat sink and a first heat dissipation element according to some embodiments of the present disclosure;

FIGS. 8 shows a cross-sectional view of an electronic device according to other embodiments of the present disclosure;

FIGS. 9 shows a cross-sectional view of an electronic device according to still other embodiments of the present disclosure;

FIGS. 10 to 12 show top views of a first heat dissipation element according to some embodiments of the present disclosure;

FIGS. 13 to 15 show cross-sectional views of an electronic device at various manufacturing stages according to some embodiments of the present disclosure;

FIGS. 16 and 17 show cross-sectional views of an electronic device at various manufacturing stages according to other embodiments of the present disclosure; and

FIGS. 18 and 19 show cross-sectional views of an electronic device at different manufacturing stages according to further embodiments of the present disclosure.

### DETAILED DESCRIPTION OF THE DISCLOSURE

Hereinafter is a detailed description of the electronic device of the embodiments of the present disclosure. It should be understood that the following description provides many various embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar and/or corresponding reference numerals may be used in various embodiments to designate similar and/or corresponding elements, in order to clearly describe the present disclosure. However, the use of these similar and/or corresponding reference numerals is only for the purpose of simply and clearly description of some embodiments of the present disclosure, and does not imply any correlation between the various embodiments and/or structures discussed.

It should be understood that, in various embodiments, relative terms such as “lower” or “bottom” or “higher” or “top” may be used to describe the relative relationship of one element to another element in the drawings. It can be appreciated that if the device in the drawings is inverted, then the element described as being on the “lower” side will become the element on the “higher” side. The embodiments of the present disclosure can be understood together with the drawings, and the drawings of the present disclosure are also considered as part of the disclosure description.

Furthermore, when it is described that a first material layer is disposed on or over a second material layer, it may include a condition where the first material layer is in contact with the second material layer, or a condition where the first material layer is not in contact with the second material layer, i.e., the condition where one or more other material layers may be interposed between the first material layer and the second material layer. However, if the first material layer is directly disposed on the second material layer, it indicates the condition where the first material layer is in contact with the second material layer.

In addition, it should be understood that ordinal numbers such as “first”, “second”, and the like used in the specification and claims are used to modify elements and are not intended to imply and represent the element(s) have any previous ordinal numbers, and do not represent the order of a certain element and another element, or the order of the manufacturing method. The use of these ordinal numbers is only used to clearly distinguish an element with a certain name and another element with the same name. The claims and the specification may not use the same terms, for example, a first element in the specification may be a second element in the claims.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is, there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to....” Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (thickness direction). In some embodiments, the schematic cross-sectional views described herein are schematic views of the YZ plane (a plane formed by the first direction D1 and the third direction D3), and the schematic top views described herein are schematic views of the XY plane (a plane formed by the first direction D1 and the second direction D2). In some embodiments, the normal direction of the electronic element, the substrate, and/or the circuit board may be the third direction D3.

In some embodiments, an optical microscope (OM), a scanning electron microscope (SEM), a thin-film thickness profiler (α-step), an ellipsometer, or other suitable methods may be used to measure the relative setting relationship, depth, thickness, width, or height of each element, or the pitch or distance between elements. According to some embodiments, a scanning electron microscope may be used to obtain a cross-sectional structural image including the element to be measured, and the depth, thickness, width, or height of each element, or the pitch or distance between elements, may be measured.

In some embodiments, when there is a "pitch" between two elements, the “pitch” represents the distance between the edge of one element and the edge of another element. In some embodiments, when an element has a “center,” the “center” represents the geometric center, the circle center, the intersection of the diagonals of the smallest rectangle covering the element, or a center defined in other manners.

In the present disclosure, the electronic device may include a display device, an antenna device, a package device, a sensing device, or a tiling device, but is not limited to. The electronic device may be a foldable or flexible electronic device. The electronic element of the electronic device may include passive and active elements, such as capacitors, resistors, inductors, diodes, transistors, etc. The diode may include a light-emitting diode or a photodiode. The package device may adopt wafer-level package (WLP) technology or panel-level package (PLP) technology, such as a chip-first process or a chip-last process, but is not limited thereto. The electronic device may include a system on a chip (SoC), a system in a package (SiP), an antenna in package (AiP), co-packaged optics (CPO), but is not limited thereto.

In addition, the appearance of the electronic device may be rectangular, circular, polygonal, a shape with curved edges, or other suitable shapes. The electronic device may have peripheral systems such as a processing system, a driving system, a control system, a light source system, or a shelving system to support a display module or a tiling module.

It should be understood that, for clarity of explanation, some elements of the electronic device may be omitted in the drawings, and some elements are schematically illustrated. In some embodiments, additional elements may be added to the electronic device described below. In other embodiments, some elements of the electronic device described below may be replaced or omitted.

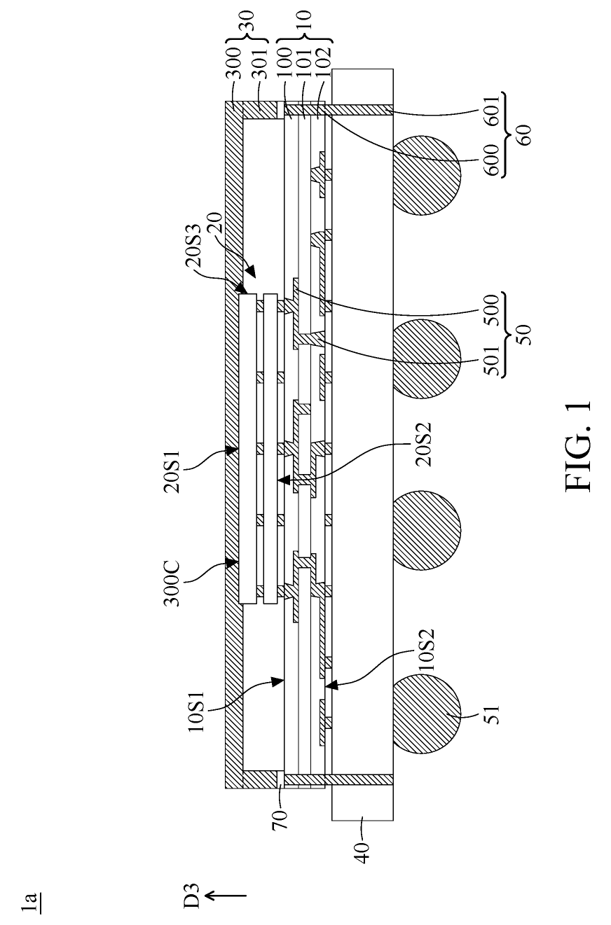

Referring to FIG. 1, a cross-sectional view of an electronic device 1a according to some embodiments of the present disclosure is illustrated. In some embodiments, the electronic device 1a may include a substrate 10, an electronic element 20, a heat sink 30, a circuit board 40, a first conductive element 50, and a first heat dissipation element 60.

In some embodiments, the substrate 10 may be a single-layer structure or a multilayer structure. Taking the multilayer structure for an example, the substrate 10 may include a core layer and one or more dielectric layers, and the dielectric layers may be disposed on one side or two sides of the core layer. In some embodiments, as shown in FIG. 1, the substrate 10 may include a dielectric layer 100 and a dielectric layer 102 disposed on two sides of the core layer 101. That is, the dielectric layer 100, the core layer 101, and the dielectric layer 102 may be stacked in sequence. In some embodiments, the dielectric layer 100, the core layer 101, and/or the dielectric layer 102 may include glass, quartz, sapphire, polyimide (PI), polydimethylsiloxane (PDMS), polycarbonate (PC), polyethylene terephthalate (PET), epoxy resin, but the present disclosure is not limited thereto. In some embodiments, in the normal direction (i.e., the third direction D3) of the substrate 10, the substrate 10 may have an upper surface 10S1 and a lower surface 10S2.

In some embodiments, the electronic element 20 may have an upper surface 20S1 and a lower surface 20S2, and the electronic element 20 may be disposed on the upper surface 10S1 of the substrate 10. In some embodiments, the electronic element 20 may be an active element and may generate heat during operation. In some embodiments, a width of the electronic element 20 may be smaller than a width of the substrate 10. In some embodiments, in a top view direction, the projection of the electronic element 20 is located within the projection of the substrate 10, without extending beyond it.

In some embodiments, the heat sink 30 may be disposed on the electronic element 20. In some embodiments, the heat sink 30 may cover the upper surface 20S1 and at least a portion of a side surface 20S3 of the electronic element 20. In some embodiments, the heat sink 30 may include a horizontal extension portion 300 and a vertical extension portion 301. In some embodiments, the horizontal extension portion 300 may be disposed on the upper surface 20S1 of the electronic element 20. In some embodiments, the horizontal extension portion 300 may be in direct contact with the upper surface 20S1 of the electronic element 20. In some embodiments, the horizontal extension portion 300 may have a recess 300C, and the electronic element 20 may be partially buried in (embedded into) the recess 300C. In this case, the recess 300C is in direct contact with the side surface 20S3 of the electronic element 20. In some embodiments, the vertical extension portion 301 may be located on at least one side of the electronic element 20 and extend from the horizontal extension portion 300 toward the substrate 10. In some embodiments, the vertical extension portion 301 may be located on multiple sides of the electronic element 20, such as on opposite sides of the electronic element 20 or surrounding all sides of the electronic element 20, increasing the contact area between the electronic element 20 and the heat sink 30 to provide more heat dissipation paths.

In some embodiments, the horizontal extension portion 300 and the vertical extension portion 301 may be integrally formed, but the present disclosure is not limited thereto. In other embodiments, the horizontal extension portion 300 and the vertical extension portion 301 may be respectively formed and connected to each other by bonding, adhesion, embedding, or other suitable processes. In some embodiments, in a top view, the vertical extension portion 301 may be continuously disposed around the periphery of the horizontal extension portion 300, or may be arranged at specific pitches at periphery of the horizontal extension portion 300.

In some embodiments, the heat sink 30 may include a high thermal conductivity material (i.e., having a relatively high thermal conductivity coefficient, k-value). Such high thermal conductivity material may include: metals, such as aluminum (Al), copper (Cu); metal alloys, such as aluminum alloys, copper alloys, and copper-aluminum alloys; ceramics, such as aluminum oxide, aluminum nitride; other suitable organic thermal dissipation materials such as thermal interface materials (TIMs); but the present disclosure is not limited thereto. In some embodiments, the horizontal extension portion 300 and the vertical extension portion 301 may include different materials to more precisely control the direction or efficiency of thermal conduction.

In some embodiments, the circuit board 40 may be disposed on the lower surface 10S2 of the substrate 10. The substrate 10 may be located between the electronic element 20 and the circuit board 40. In some embodiments, the circuit board 40 may include a flexible printed circuit board (FPC), a rigid printed circuit board (rigid PCB), a multilayer PCB, a high-density interconnect PCB (HDI PCB), a transparent PCB, other suitable circuit boards, but the present disclosure is not limited thereto.

In some embodiments, the first conductive element 50 may penetrate the substrate 10 and electrically connect the electronic element 20 and the circuit board 40. In some embodiments, the first conductive element 50 may include a horizontal extension portion 500 and a vertical extension portion 501. The horizontal extension portion 500 extends in the horizontal direction of the substrate 10 and may be used to connect features located at the same height. The vertical extension portion 501 extends in the vertical direction (i.e., the normal direction or the third direction D3) of the substrate 10 and may be used to be connected to features located at different heights. In some embodiments, the first conductive element 50 may be a redistribution layer (RDL) or a fan-out trace, but the present disclosure is not limited thereto. In other embodiments, the first conductive element 50 may further include vias, such as through vias, blind vias, buried vias, or combinations thereof.

In some embodiments, the first conductive element 50 may include conductive materials. For example, such conductive material may include metals, metal alloys, metal compounds, other suitable conductive materials, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), or alloys thereof. For example, the metal compound may be tantalum nitride (TaN), titanium nitride (TiN), tungsten silicide (WSi₂), indium tin oxide (ITO), etc. In some embodiments, the horizontal extension portion 500 and the vertical extension portion 501 may include different materials to more precisely control the transmission of electrical signals.

In some embodiments, the first heat dissipation element 60 may penetrate the substrate 10 and the circuit board 40, and the first heat dissipation element 60 may thermally exchange with the heat sink 30. For example, the first heat dissipation element 60 may be in direct contact with the heat sink 30, or may be indirect contact with the heat sink 30 by an adhesive (e.g., an adhesive element 70 to be mentioned below) disposed therebetween to carry out the thermal exchange function by thermal conduction. In some embodiments, the first heat dissipation element 60 is used for conduction of heat energy rather than transmission of electrical signal. Therefore, the first heat dissipation element 60 may be electrically isolated from the electronic element 20. In some embodiments, one or more first heat dissipation elements 60 may be provided.

In some embodiments, the first heat dissipation element 60 may include a first portion 600 and a second portion 601, wherein the first portion 600 may be located in the substrate 10, and the second portion 601 may be located in the circuit board 40. In some embodiments, the first portion 600 and the second portion 601 may be integrally formed, but the present disclosure is not limited thereto. In other embodiments, the first portion 600 and the second portion 601 may be respectively formed and connected to each other by bonding, adhesion, embedding, or other suitable processes.

In some embodiments, the first heat dissipation element 60 may include high thermal conductivity materials, and such high thermal conductivity materials may be similar to the heat sink 30, but the present disclosure is not limited thereto. In some embodiments, the first portion 600 and the second portion 601 of the first heat dissipation element 60 may include different materials. For example, a thermal conductivity coefficient of the first portion 600 may be lower than a thermal conductivity coefficient of the second portion 601 to more precisely control the direction or efficiency of heat conduction.

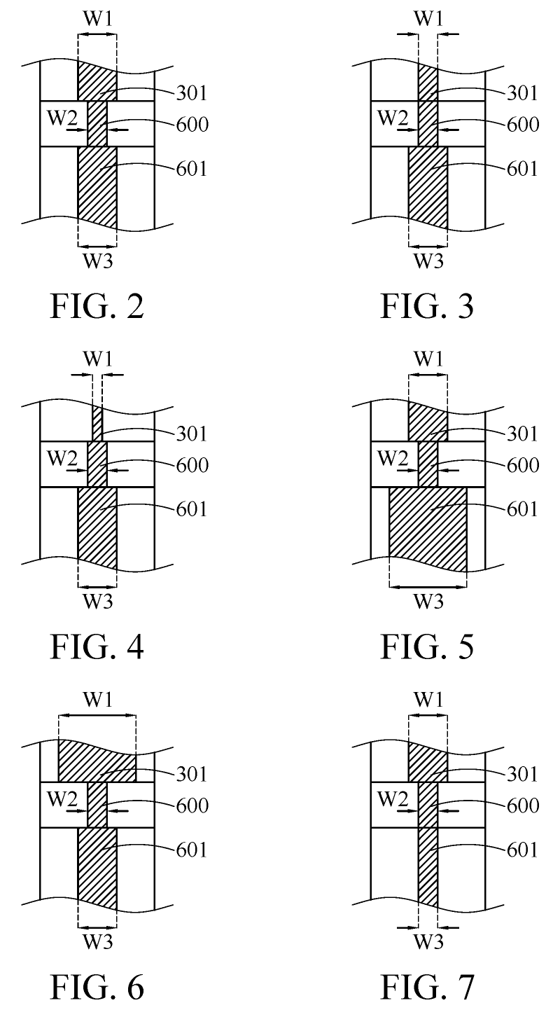

Referring FIGS. 2 to 7, cross-sectional views of the heat sink 30 and the first heat dissipation element 60 according to some embodiments of the present disclosure are illustrated. In some embodiments, as shown in FIGS. 2 to 7, the vertical extension portion 301 of the heat sink 30 may have a first width w1, the first portion 600 of the first heat dissipation element 60 may have a second width w2, and the second portion 601 of the first heat dissipation element 60 may have a third width w3.

In some embodiments, when a thermal conductivity of the heat sink 30 is greater than a thermal conductivity of the first heat dissipation element 60, the heat sink 30 and the first heat dissipation element 60 may present relative relationships as shown in FIGS. 2, 3, 4, and 5. As shown in FIG. 2, the first width w1 of the vertical extension portion 301 is equal to the third width w3 of the second portion 601, and the first width w1 of the vertical extension portion 301 is greater than the second width w2 of the first portion 600 (i.e., w1=w3>w2). As shown in FIG. 3, the first width w1 of the vertical extension portion 301 is equal to the second width w2 of the first portion 600, and the first width w1 of the vertical extension portion 301 is smaller than the third width w3 of the second portion 601 (i.e., w1=w2<w3). As shown in FIG. 4, the first width w1 of the vertical extension portion 301 is smaller than the second width w2 of the first portion 600, and the second width w2 of the first portion 600 is smaller than the third width w3 of the second portion 601 (i.e., w1<w2<w3). As shown in FIG. 5, the second width w2 of the first portion 600 is smaller than the first width w1 of the vertical extension portion 301, and the first width w1 of the vertical extension portion 301 is smaller than the third width w3 of the second portion 601 (i.e., w2 < w1 < w3).

In some embodiments, when the thermal conductivity of the heat sink 30 is less than the thermal conductivity of the first heat dissipation element 60, the heat sink 30 and the first heat dissipation element 60 may present relative relationships as shown in FIGS. 2, 3, 6, and 7. The relationships shown in FIGS. 2 and 3 may refer to the above description and will not be repeated here. As shown in FIG. 6, the second width w2 of the first portion 600 is smaller than the third width w3 of the second portion 601, and the third width w3 of the second portion 601 is smaller than the first width w1 of the vertical extension portion 301 (i.e., w2<w3<w1). As shown in FIG. 7, the second width w2 of the first portion 600 is equal to the third width w3 of the second portion 601, and the second width w2 of the first portion 600 is smaller than the first width w1 of the vertical extension portion 301 (i.e., w2=w3<w1).

First, description is given with respect to the first heat dissipation member 60. In some embodiments, as shown in FIGS. 2 to 7, the third width w3 of the second portion 601 of the first heat dissipation element 60 may all be greater than or equal to the second width w2 of the first portion 600 of the first heat dissipation element 60. As a result, the second portion 601 may have a heat dissipation capability equal to or greater than a heat dissipation capability of the first portion 600, thereby ensuring that heat energy is transferred from the first portion 600 of the first heat dissipation element 60 toward the second portion 601 to avoid accumulation of heat energy in the first portion 600. In detail, when a size (e.g., the third width w3 or a corresponding cross-sectional area) of the second portion 601 is greater than a size (e.g., the second width w2 or a corresponding cross-sectional area) of the first portion 600, and when the thermal conductivity of the second portion 601 is substantially same as the thermal conductivity of the first portion 600, the second portion 601 may have the heat dissipation capability greater than the heat dissipation capability of the first portion 600. Therefore, by adjusting the dimensional relationship between the second portion 601 and the first portion 600, the direction (for example, flowing in an opposite direction of the third direction D3) of heat flow of heat energy can be controlled to achieve active heat dissipation.

Next, the heat sink 30 and the first heat dissipation element 60 are described below. In some embodiments, as shown in FIGS. 2, 3, 4, and 5, when the thermal conductivity of the heat sink 30 is greater than the thermal conductivity of the first heat dissipation element 60, the first width w1 of the vertical extension 301 may be greater than, equal to, or smaller than the second width w2 of the first portion 600, each of which allows heat energy to be transferred from the vertical extension 301 of the heat sink 30 toward the first portion 600 of the first heat dissipation element 60. In addition, the third width w3 of the second portion 601 is greater than or equal to the first width w1 of the vertical extension 301. As a result, by increasing the size of the second portion 601, the heat dissipation capability of the second portion 601 can sufficiently match a heat dissipation capability of the vertical extension 301, thereby avoiding heat accumulation in the first portion 600.

In other embodiment, as shown in FIGS. 2, 3, 6, and 7, when the thermal conductivity of the heat sink 30 is smaller than the thermal conductivity of the first heat dissipation element 60, the first width w1 of the vertical extension 301 is greater than or equal to the second width w2 of the first portion 600, such that heat energy is transferred from the vertical extension 301 toward the first portion 600. In addition, the third width w3 of the second portion 601 may be greater than, equal to, or smaller than the first width w1 of the vertical extension 301, each of which allows heat to be steadily transferred from the vertical extension 301 toward the first portion 600.

In some embodiments, as shown in FIGS. 5 and 6, the second width w2 of the first portion 600 may be smaller than the first width w1 of the vertical extension 301 and the third width w3 of the second portion 601 (i.e., w2<w1 and w2<w3). In addition, the first width w1 of the vertical extension 301 may be greater than or smaller than the third width w3 of the second portion 601. For example, a ratio (w1/w3) between the first width w1 of the vertical extension 301 and the third width w3 of the second portion 601 may be between 0.6 and 1.5.

Accordingly, the present disclosure may achieve active heat dissipation of the electronic element 20 by the above-mentioned configuration (e.g., FIGS. 2 to 7). That is, a heat flow direction is a direction from the electronic element 20 toward the circuit board 40.

Returning to FIG. 1, as shown therein, in some embodiments, the electronic device 1a may further include an adhesive element 70, and the adhesive element 70 may be disposed between the heat sink 30 and the first heat dissipation element 60. For example, in some embodiments, the adhesive element 70 may have similar material as dielectric layer 102. In some embodiments, the adhesive element 70 may include a high thermal conductivity material, such as the ones mentioned above, but the present disclosure is not limited thereto.

In some embodiments, the electronic device 1a may further include a second conductive element 51, and the second conductive element 51 may be disposed on the circuit board 40. Specifically, the circuit board 40 may be located between the second conductive element 51 and the substrate 10. In some embodiments, the second conductive element 51 may be used to carry out electrical connection between the circuit board 40 and other electronic devices. Therefore, the second conductive element 51 is not in direct contact with the first heat dissipation element 60 (or a second heat dissipation element 61 mentioned below) to avoid electrical connection therebetween. However, the present disclosure is not limited thereto. In other embodiments, the second conductive element 51 is used to carry out physical connection between the circuit board 40 and other electronic devices, rather than electrical connection. In this case, the second conductive element 51 may be in direct contact with or in indirect contact with the first heat dissipation element 60 (or the second heat dissipation element 61 mentioned below). In some embodiments, the second conductive element 51 may include conductive materials, such as those mentioned above, but the present disclosure is not limited thereto. In some embodiments, the second conductive element 51 is a solder ball or the like.

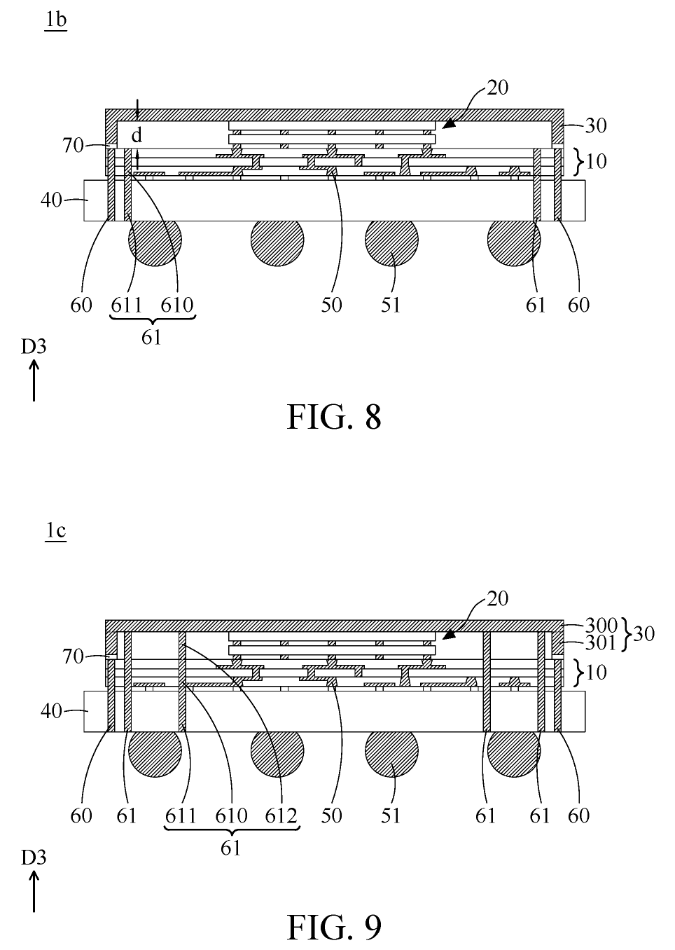

Referring to FIG. 8, a cross-sectional view of an electronic device 1b according to other embodiments of the present disclosure is illustrated. The electronic device 1b differs from the electronic device 1a of FIG. 1 in that the electronic device 1b may further include a second heat dissipation element 61, and the second heat dissipation element 61 may penetrate the substrate 10 and the circuit board 40. In some embodiments, the second heat dissipation element 61 may be located between the first heat dissipation element 60 and the electronic element 20. In some embodiments, the first heat dissipation element 60 may surround the second heat dissipation element 61, and the second heat dissipation element 61 may surround the electronic element 20. In some embodiments, one or more second heat dissipation elements 61 may be provided. In some embodiments, the second heat dissipation element 61 is used to further enhance a heat dissipation capability of the electronic device 1b, and is not used for transmission of electrical signal. Therefore, the second heat dissipation element 61 may be electrically isolated from the electronic element 20. In some embodiments, the second heat dissipation element 61 is not in direct contact with the vertical extension 301 of the heat sink 30, nor in direct contact with the horizontal extension 300 of the heat sink 30. In other words, the second heat dissipation element 61 is spaced a distance d apart from the heat sink 30.

In some embodiments, the second heat dissipation element 61 may include a third portion 610 and a fourth portion 611. The third portion 610 may be located in the substrate 10, and the fourth portion 611 may be located in the circuit board 40. In some embodiments, the third portion 610 and the fourth portion 611 may be integrally formed, but the present disclosure is not limited thereto. In other embodiments, the third portion 610 and the fourth portion 611 may be respectively formed and connected to each other by bonding, adhesion, embedding, or other suitable processes.

In some embodiments, the second heat dissipation element 61 may include high thermal conductivity materials, such as those mentioned above, but the present disclosure is not limited thereto. In some embodiments, the third portion 610 and the fourth portion 611 of the second heat dissipation element 61 may include different materials to more precisely control the direction or efficiency of heat conduction.

In some embodiments, a size (e.g., width) of the second heat dissipation element 61 may be different from the size of the first heat dissipation element 60. For example, since the second heat dissipation element 61 is closer to the electronic element 20 than the first heat dissipation element 60 (i.e., located in a region of higher wiring density), the size of the second heat dissipation element 61 may be smaller than the size of the first heat dissipation element 60 to avoid affecting wiring requirements. Alternatively, since the second heat dissipation element 61 is closer to the electronic element 20 than the first heat dissipation element 60 (i.e., closer to the heat source), the size of the second heat dissipation element 61 may be greater than the size of the first heat dissipation element 60 to enhance the heat dissipation effect for the electronic element 20.

In some embodiments, the number of second heat dissipation elements 61 may be multiple. For example, second heat dissipation elements 61 may be provided on two opposite sides of the electronic element 20 to enhance the heat dissipation effect for the electronic element 20. In some embodiments, the pitch between the second heat dissipation element 61 and the electronic element 20 may be different (as shown by the two second heat dissipation elements 61 in FIG. 8). For example, in a region of lower wiring density, the number of circuits serving as good conductors of electricity and heat is smaller, making it more difficult for heat energy to be conducted to the external environment. Therefore, the second heat dissipation element 61 in the region of lower wiring density may be closer to the electronic element 20 to enhance the heat dissipation effect for the electronic element 20.

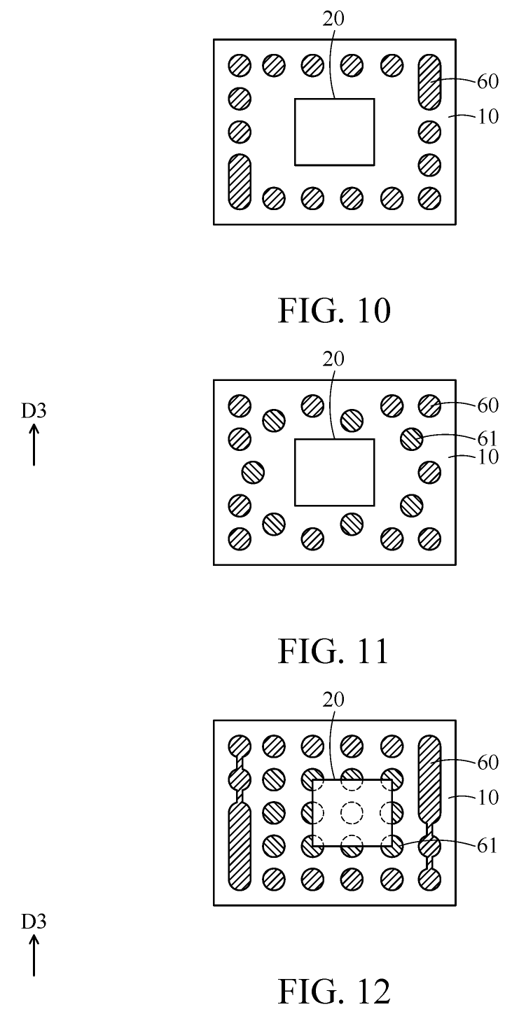

Referring to FIG. 9, a cross-sectional view of an electronic device 1c according to still other embodiment of the present disclosure is illustrated. The electronic device 1c differs from the electronic device 1b of FIG. 8 in that the second heat dissipation element 61 of the electronic device 1c may further include a fifth portion 612, and the fifth portion 612 may be in direct contact with the horizontal extension 300 of the heat sink 30. As a result, the second heat dissipation element 61 may penetrate the substrate 10 and the circuit board 40, and extend toward the horizontal extension 300 of the heat sink 30 until contacting the horizontal extension 300. In other words, the second heat dissipation element 61 thermally exchanges with the heat sink 30.

In some embodiments, the number of second heat dissipation elements 61 may be multiple. For example, multiple second heat dissipation elements 61 may be provided on the same side of the electronic element 20 to enhance the heat dissipation effect for the electronic element 20. Taking FIG. 9 as an example, there are two heat dissipation elements 61 on each of the left side and right side of the electronic element 20, but the present disclosure is not limited thereto. In other embodiments, more than two second heat dissipation elements 61 may be provided on one side of the electronic element 20. Alternatively, different numbers of second heat dissipation elements 61 may be provided on each of the left side and the right side of the electronic element 20. For example, in the side with lower wiring density, the number of circuits serving as good conductors of electricity and heat is relatively small, making it more difficult for heat to be conducted to the external environment. Therefore, more second heat dissipation elements61 may be provided on the side with lower wiring density to enhance the heat dissipation effect for the electronic element 20.

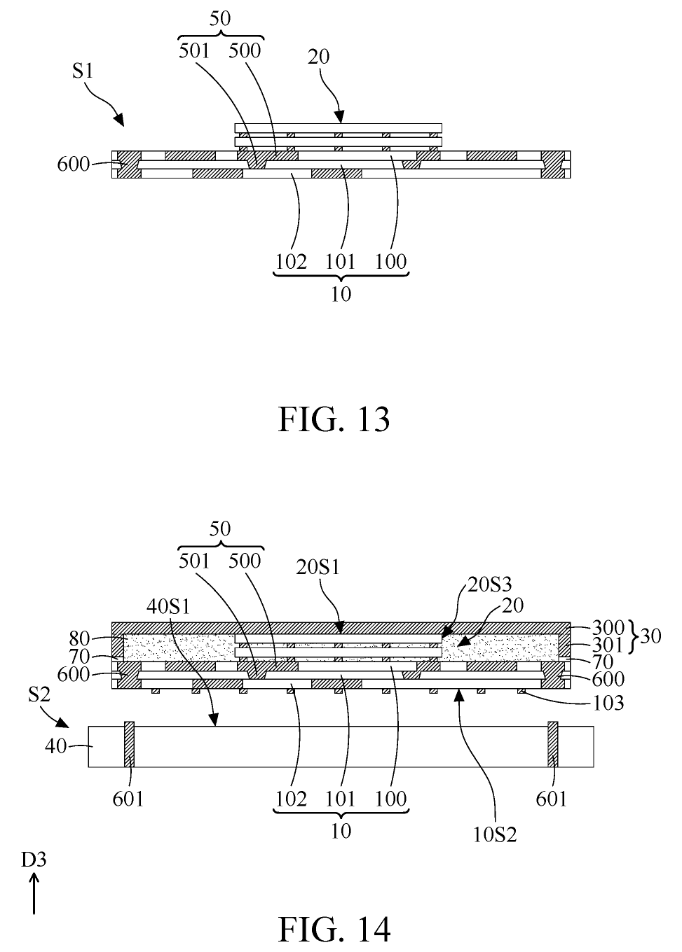

Referring to FIGS. 10 to 12, a top view of the first heat dissipation element 60 according to some embodiments of the present disclosure is respectively illustrated. For ease of understanding, the first heat dissipation element 60, the substrate 10, and the electronic element 20 are shown in the drawings, while other elements are omitted. As shown in FIG. 10, in some embodiments, in a top view, the first heat dissipation element 60 may be arranged around the electronic element 20. In some embodiments, the first heat dissipation element 60 may be arranged around the electronic element 20 at specific pitches. For example, a pitch between two adjacent first heat dissipation elements 60 may be a constant, but the present disclosure is not limited thereto. In some embodiments, in a top view, an area of the first heat dissipation element 60 corresponding to a corner of the electronic element 20 may be greater than an area of the first heat dissipation element 60 corresponding to a side of the electronic element 20 to enhance the heat dissipation effect for the corner of the electronic element 20.

As shown in FIG. 11, in some embodiments, in a top view, the first heat dissipation element 60 may be arranged to surround the electronic element 20, and the second heat dissipation element 61 may be located between the first heat dissipation element 60 and the electronic element 20. In some embodiments, the first heat dissipation element 60 and the second heat dissipation element 61 may be alternately arranged with fixed or variable spacing, or placed in any manners. In some embodiments, the top-view profiles of the first heat dissipation element 60 and the second heat dissipation element 61 may be rectangular, circular, polygonal, shapes with curved edges, or other suitable shapes. In some embodiments, the areas of the first heat dissipation element 60 and the second heat dissipation element 61 may be the same or different. In some embodiments, the area of the first heat dissipation element 60 and the area of the second heat dissipation element 61 may be the same or different.

As shown in FIG. 12, in some embodiments, in a top view, the first heat dissipation element 60 may be arranged to surround the electronic element 20, and the second heat dissipation element 61 may partially or completely overlap the electronic element 20. In other words, the second heat dissipation element 61 may be located below the electronic element 20 to enhance heat dissipation efficiency for the electronic element 20. In some embodiments, the second heat dissipation element 61 may be in direct contact with the electronic element 20 or in indirect contact with the electronic element 20, but is not electrically connected the electronic element 20.

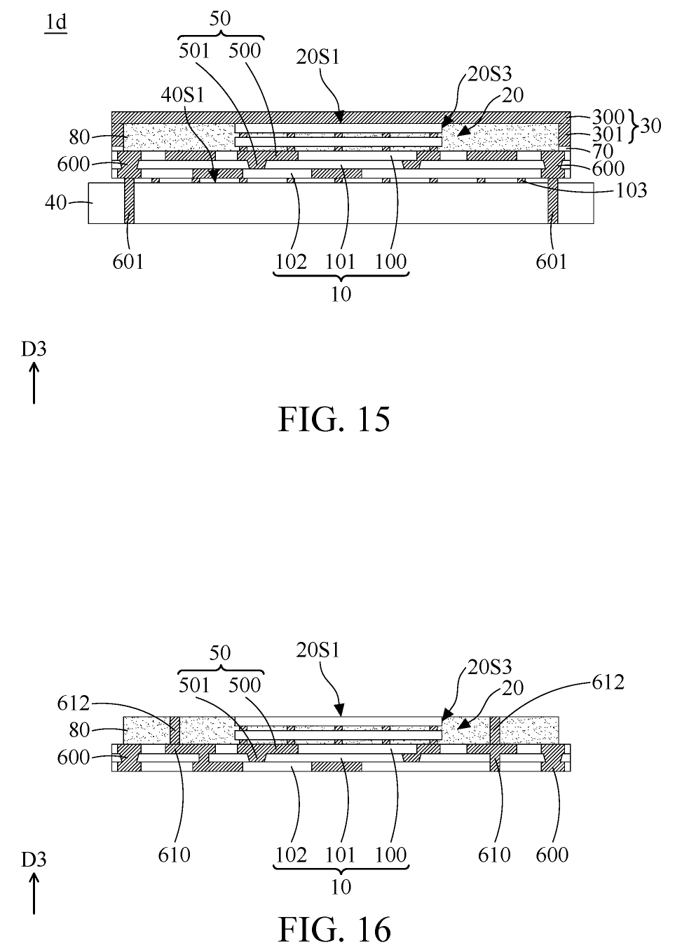

Referring to FIGS. 13 to 15, a cross-sectional view of an electronic device 1d at different manufacturing stages according to some embodiments of the present disclosure is respectively illustrated. As shown in FIG. 13, a first stack S1 is provided, and the first stack S1 may include the substrate 10, the first conductive element 50, and the first portion 600 of the first heat dissipation element 60. The substrate 10 may include the dielectric layer 100, the core layer 101, and the dielectric layer 102 sequentially stacked, and the first conductive element 50 and the first portion 600 of the first heat dissipation element 60 respectively penetrate the substrate 10. For example, the core layer 101 may be provided; multiple through vias may be formed in the core layer 101 by a drilling process; the vertical extension 501 of the first conductive element 50 may be formed in a portion of the through vias by a deposition process; a first portion 600 of the first heat dissipation element 60 may be formed in another portion of the through vias by a deposition process; the horizontal extension 500 of the first conductive element 50 may be formed on the core layer 101 by a combination of photolithography and etching processes; and the dielectric layer 100 and the dielectric layer 102 may be formed on the core layer 101 by a build-up process to obtain the first stack S1 as shown in FIG. 13. In some embodiments, at least a portion of the first conductive element 50 and at least a portion of the first heat dissipation element 60 may be formed in the same or different processes.

In some embodiments, the drilling process may include mechanical drilling, laser drilling, etching drilling, other suitable processes, but the present disclosure is not limited thereto. In some embodiments, the deposition process may include electroplating, chemical plating, physical vapor deposition (PVD), chemical vapor deposition (CVD), other suitable processes, but the present disclosure is not limited thereto. In some embodiments, the photolithography process may include photoresist application (e.g., spin-on coating, lamination), soft baking, mask aligning, exposure, post-exposure baking, photoresist developing, rinsing, drying (e.g., spin-drying and/or hard baking), other suitable photolithography techniques and/but the present disclosure is not limited thereto. In some embodiments, the etching process may include dry etching, wet etching, other suitable etching processes, but the present disclosure is not limited thereto. In some embodiments, the build-up process may include a thermal pressing process, other suitable processes, but the present disclosure is not limited thereto.

Next, the electronic element 20 may be disposed on the substrate 10. For example, the electronic element 20 may be electrically and/or physically connected to the substrate 10 by pads, solder balls, other elements, but the present disclosure is not limited thereto.

As shown in FIG. 14, next, a package material 80 may be disposed on the electronic element 20 to encapsulate the side surface 20S3 of the electronic element 20 while exposing the upper surface 20S1 of the electronic element 20. In some embodiments, the package material 80 may include an epoxy molding compound (EMC), a silicone molding material, other suitable materials, but the present disclosure is not limited thereto. In some embodiments, the package material 80 may further be doped with high thermal conductivity materials such as aluminum nitride (AlN), aluminum oxide (Al₂O₃), or boron nitride (BN) to further improve heat dissipation performance.

Next, the heat sink 30 may be disposed on the electronic element 20. Specifically, the adhesive element 70 may be disposed on the first portion 600 of the first heat dissipation element 60; and the vertical extension 301 of the heat sink 30 may be connected to the first portion 600 of the first heat dissipation element 60 by the adhesive element 70. In some embodiments, the adhesive element 70 may be omitted, and the vertical extension 301 may be directly disposed on the first portion 600 of the first heat dissipation element 60 by a bonding process (e.g., thermal process). In this case, a bonding interface between the vertical extension 301 and the first portion 600 of the first heat dissipation element 60 may include a eutectic mixture. In some embodiments, the vertical extension 301 and the first portion 600 of the first heat dissipation element 60 may partially or completely overlap.

Next, a second stack S2 may be provided, and the second stack S2 may include the circuit board 40 and the second portion 601 of the first heat dissipation element 60. The second portion 601 of the first heat dissipation element 60 may penetrate the circuit board 40 and protrude from an upper surface 40S1 of the circuit board 40. Specifically, a connector 103, such as a pad, may be disposed on a lower surface 10S2 of the substrate 10. Therefore, the second portion 601 may protrude from the upper surface 40S1 of the circuit board 40 at a height corresponding to the connector 103 to facilitate bonding between the second portion 601 of the first heat dissipation element 60 and the vertical extension 301 of the heat sink 30. In some embodiments, the second portion 601 of the first heat dissipation element 60 may be formed by a deposition process, but the present disclosure is not limited thereto. In other embodiments, the second portion 601 of the first heat dissipation element 60 may be pre-formed and inserted into the through vias of the circuit board 40.

As shown in FIG. 15, next, the circuit board 40 and the substrate 10 are bonded. After bonding, the first conductive element 50 may electrically connect the electronic element 20 to the circuit board 40. In addition, the first portion 600 of the first heat dissipation element 60 may physically connect the second portion 601, and may thermally exchange with the heat sink 30. As a result, the electronic device 1d may be formed.

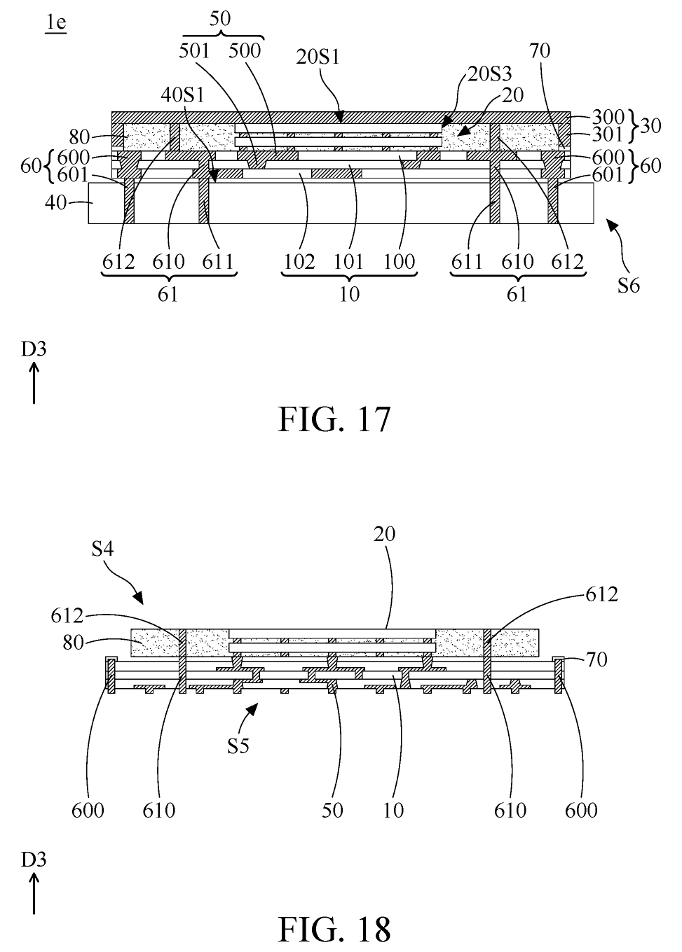

Referring to FIGS. 16 and 17, a cross-sectional view of an electronic device 1e at different manufacturing stages according to other embodiments of the present disclosure is respectively illustrated. FIG. 16 continues with the steps shown in FIG. 13. In these embodiments, the second heat dissipation element 61 may additionally be formed in the electronic device by adjusting the steps shown in FIG. 13 in combination with the steps shown in FIGS. 16 and 17. For example, the steps shown in FIG. 13 may be performed, and during the formation of the first portion 600 of the first heat dissipation element 60, or during the formation of the first conductive element 50, the third portion 610 of the second heat dissipation element 61 is additionally formed in the substrate 10 using a similar or the same process.

As shown in FIG. 16, next, a through via 800 may be formed in the package material 80, wherein the through via 800 may expose the third portion 610 of the second heat dissipation element 61. Continuing with the above steps, the fifth portion 612 of the second heat dissipation element 61 may be formed in the through via 800.

As shown in FIG. 17, next, a third stack S3 may be provided, and the third stack S3 may include the circuit board 40, the second portion 601 of the first heat dissipation element 60, and the fourth portion 611 of the second heat dissipation element 61. The second portion 601 of the first heat dissipation element 60 may penetrate the circuit board 40 and may protrude from the upper surface 40S1 of the circuit board 40. In addition, the fourth portion 611 of the second heat dissipation element 61 may penetrate the circuit board 40 and may protrude from the upper surface 40S1 of the circuit board 40. In some embodiments, the fourth portion 611 of the second heat dissipation element 61 may be formed by a deposition process, but the present disclosure is not limited thereto. In other embodiments, the fourth portion 611 of the second heat dissipation element 61 may be pre-formed and inserted into the through via of the circuit board 40.

Next, the circuit board 40 and the substrate 10 may be bonded together. After bonding, the first conductive element 50 may electrically connect the electronic element 20 to the circuit board 40. In addition, the first portion 600 of the first heat dissipation element 60 may physically connect the second portion 601, and the third portion 610 of the second heat dissipation element 61 may physically connect the fourth portion 611. As a result, the electronic device 1e may be formed. It is worth noting that in the electronic device 1e, the fourth portion 611 and the fifth portion 612 of the second heat dissipation element 61 may be non-overlapping in the vertical direction (i.e., the third direction D3) to enhance design flexibility of the electronic device 1e.

However, the present disclosure is not limited thereto. In other embodiments, the fourth portion 611 and the fifth portion 612 of the electronic device may overlap in the vertical direction (i.e., the third direction D3) to reduce the path required for heat energy transfer and thereby improve the heat dissipation capability of the electronic device.

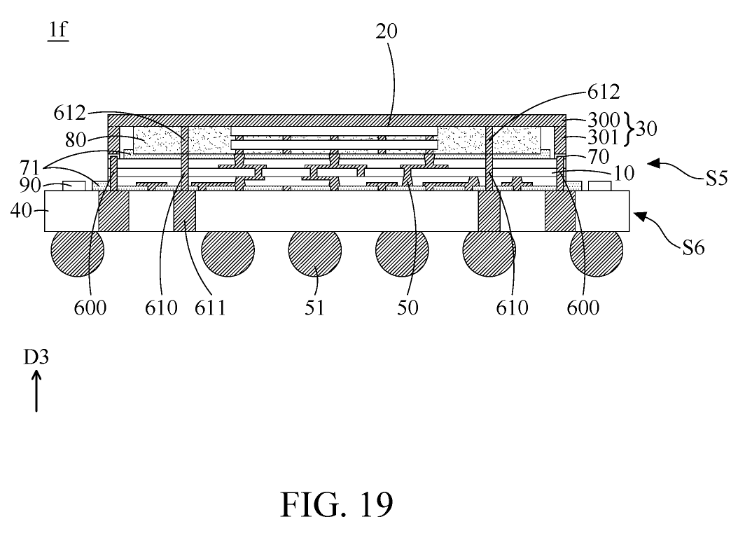

FIGS. 18 and 19, a cross-sectional view of the electronic device 1f at different manufacturing stages according to further embodiments of the present disclosure is respectively illustrated. As shown in FIG. 18, a fourth stack S4 may be provided, and the fourth stack S4 may include the electronic element 20, the package material 80, and the fifth portion 612 of the second heat dissipation element 61. The package material 80 may encapsulate the side surface 20S3 of the electronic element 20 while exposing the upper surface 20S1 and the lower surface 20S2 of the electronic element 20. In addition, the fifth portion 612 of the second heat dissipation element 61 may penetrate the package material 80. For example, the electronic element 20 may be disposed on a temporary substrate (not shown); the package material 80 may be formed to encapsulate the side surface 20S3 of the electronic element 20; the through vias may be formed in the package material 80; and the fifth portion 612 of the second heat dissipation element 61 may be formed in the through vias by a deposition process; and the temporary substrate may be removed to obtain the fourth stack S4 as shown in FIG. 18.

Next, the fifth stack S5 may be provided, and the fifth stack S5 may include the substrate 10, the first conductive element 50, the first portion 600 of the first heat dissipation element 60, the third portion 610 of the second heat dissipation element 61, and the adhesive element 70. The method of disposing these elements may refer to the foregoing description and is not repeated herein.

Next, the fourth stack S4 and the fifth stack S5 may be bonded together. After bonding, the first conductive element 50 may electrically connect the electronic element 20. In addition, the third portion 610 of the second heat dissipation element 61 may physically connect the fifth portion 612.

As shown in FIG. 19, next, the fourth stack S4 and the fifth stack S5 may be fixed by an adhesive layer 71. That is, the adhesive layer 71 is disposed between the package material 80 and the substrate 10. For example, the adhesive layer 71 may be filled between the fourth stack S4 and the fifth stack S5 before, during, or after a bonding process to fix the two. In some embodiments, the adhesive layer 71 may include an underfill material, such as a capillary underfill (CUF), a no-flow underfill (NUF), a molded underfill (MUF), other suitable underfill materials, but the present disclosure is not limited thereto.

Next, a sixth stack S6 may be provided, and the sixth stack S6 may include the circuit board 40, the second portion 601 of the first heat dissipation element 60, the fourth portion 611 of the second heat dissipation element 61, the second conductive element 51, and an alignment element 90. The second portion 601 of the first heat dissipation element 60 and the fourth portion 611 of the second heat dissipation element 61 may respectively penetrate the circuit board 40. In addition, the alignment element 90 may be disposed on the circuit board 40 and located at one side of the electronic element 20 to serve as an alignment mark for subsequent processes. In some embodiments, the alignment element 90 may be disposed on a periphery or a corner region of the circuit board 40, but the present disclosure is not limited thereto. In some embodiments, the alignment element 90 may include metal, ink, or other suitable positioning materials, but the present disclosure is not limited thereto.

Next, the fifth stack S5 may be bonded onto the sixth stack S6. After bonding, the circuit board 40 electrically connects the electronic element 20 by the first conductive element 50, the second portion 601 of the first heat dissipation element 60 physically connects the first portion 600, and the fourth portion 611 of the second heat dissipation element 61 physically connects the third portion 610. In some embodiments, the fifth stack S5 and the sixth stack S6 may be fixed by the adhesive layer 72. That is, the adhesive layer 72 is disposed between the substrate 10 and the circuit board 40. For example, the adhesive layer 72 may be disposed between the fifth stack S5 and the sixth stack S6 before, during, or after the bonding process to fix the two stacks together. In some embodiments, the adhesive layer 72 may include an underfill material, such as that mentioned above, but the present disclosure is not limited thereto.

Next, the heat sink 30 is bonded onto the electronic element 20. After bonding, the vertical extension portion 301 of the heat sink 30 physically connects the first portion 600 of the first heat dissipation element 60, and the horizontal extension portion 300 of the heat sink 30 physically connects the fifth portion 612 of the second heat dissipation element 61. As a result, the electronic device 1f may be formed.

It is worth mentioning that although some manufacturing methods of the electronic device have been described above, the present disclosure is not limited thereto. A person having ordinary skill in the art may, according to design requirements, arbitrarily combine or adjust the various processes mentioned above to form various electronic devices similar or same as those described above. That is, although the foregoing mentions the formation of the first heat dissipation element 60 or the second heat dissipation element 61 in a stepwise manner by a deposition process, in other embodiments, the first heat dissipation element 60 or second heat dissipation element 61 may also be integrally formed. For example, the first heat dissipation element 60 or the second heat dissipation element 61 may be formed in a single process by casting process or other suitable processes. Furthermore, the heat sink 30 and the first heat dissipation element 60 and/or the second heat dissipation element 61 may also be integrally formed. For example, a casting process or other suitable processes may be used to form, in a single process, a combination of the heat sink 30 and the first heat-dissipating member 60 (or the second heat-dissipating member 61), such that they are embedded in the substrate 10 and the circuit board 40. Accordingly, it is understood that the steps described above are merely for facilitating the understanding of the present disclosure, and are not intended to limit the present disclosure.

In summary, the present disclosure provides an electronic device which, through the combination of a heat sink and a heat dissipation element (e.g., the first heat dissipation element or the second heat dissipation element), effectively enhances the heat dissipation performance of the electronic device. In addition, according to the dimensional relationship between the heat sink and the heat dissipation element, the present disclosure also effectively controls the heat flow direction of heat energy to achieve an active heat dissipation effect.

The features between the embodiments of the present disclosure may be arbitrarily combined as long as they do not violate or conflict with the spirit of the disclosure. In addition, the scope of the present disclosure is not limited thereto the process, machine, manufacturing, material composition, device, method, and step in the specific embodiments described in the specification. A person of ordinary skill in the art will understand current and future process, machine, manufacturing, material composition, device, method, and step from the content disclosed in the present disclosure, as long as the current or future process, machine, manufacturing, material composition, device, method, and step performs substantially the same functions or obtain substantially the same results as the present disclosure. Therefore, the scope of the present disclosure includes the above-mentioned process, machine, manufacturing, material composition, device, method, and steps. The scope of the present disclosure should be determined by the scope of the claims. It is not necessary for any embodiment or claim of the present disclosure to achieve all of the objects, advantages, and/or features disclosed herein.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation to encompass all such modifications and similar arrangements.

What is claimed is:

1. An electronic device, comprising:
a substrate having an upper surface and a lower surface opposite to the upper surface;
an electronic element disposed on the upper surface of the substrate;
a heat sink disposed on the electronic element;
a circuit board disposed on the lower surface of the substrate;
a first conductive element penetrating the substrate and electrically connecting the electronic element and the circuit board; and
a first heat dissipation element penetrating the substrate and the circuit board, wherein the first heat dissipation element thermally exchanges with the heat sink.

2. The electronic device as claimed in claim 1, wherein the first heat dissipation element comprises a first portion and a second portion, the first portion being located in the substrate, and the second portion being located in the circuit board, wherein a width of the second portion is greater than or equal to a width of the first portion.

3. The electronic device as claimed in claim 2, wherein a thermal conductivity of the heat sink is greater than a thermal conductivity of the first heat dissipation element, and the width of the second portion is greater than the width of the first portion.

4. The electronic device as claimed in claim 3, wherein the width of the second portion is greater than or equal to a width of the heat sink.

5. The electronic device as claimed in claim 2, wherein a thermal conductivity of the heat sink is less than a thermal conductivity of the first heat dissipation element, and wherein the width of the second portion is greater than or equal to the width of the first portion.

6. The electronic device as claimed in claim 5, wherein the width of the second portion is equal to the width of the first portion, and a width of the heat sink is greater than the width of the second portion.

7. The electronic device as claimed in claim 1, wherein the heat sink comprises a horizontal extension portion and a vertical extension portion, the horizontal extension portion being disposed on the upper surface of the electronic element, and the vertical extension portion extending from the horizontal extension portion toward the substrate.

8. The electronic device as claimed in claim 7, wherein the horizontal extension portion is in contact with the upper surface of the electronic element.

9. The electronic device as claimed in claim 8, wherein the horizontal extension portion comprises a recess, and the recess is in contact with a side surface of the electronic element.

10. The electronic device as claimed in claim 1, wherein in a top view, the first heat dissipation element surrounds the electronic element.

11. The electronic device as claimed in claim 1, further comprising: a second heat dissipation element penetrating the substrate and the circuit board, wherein the second heat dissipation element is located between the first heat dissipation element and the electronic element.

12. The electronic device as claimed in claim 11, wherein the second heat dissipation element thermally exchanges with the heat sink.

13. The electronic device as claimed in claim 11, wherein the second heat dissipation element is spaced a distance apart from the heat sink.

14. The electronic device as claimed in claim 11, wherein in a top view, the second heat dissipation element overlaps the electronic element.

15. The electronic device as claimed in claim 1, wherein the first heat dissipation element is electrically isolated from the electronic element.

16. The electronic device as claimed in claim 1, further comprising: an adhesive element disposed between the heat sink and the first heat dissipation element.

17. The electronic device as claimed in claim 1, further comprising: a package material disposed between the heat sink and the substrate, and encapsulating a side surface of the electronic element.

18. The electronic device as claimed in claim 17, further comprising: an adhesive layer disposed between the package material and the substrate, or disposed between the substrate and the circuit board.

19. The electronic device as claimed in claim 1, further comprising: a second conductive element disposed on the circuit board, wherein the circuit board is located between the second conductive element and the substrate.

20. The electronic device as claimed in claim 1, further comprising: an alignment element disposed on the circuit board and located at a side of the electronic element.
